(19) United States
(12) Patent Application Publication
(10) Pub. No.: US 2025/0164680 A1
(43) Pub. Date: May 22, 2025

(54) OPTICAL DEVICE

(71) Applicants: COMMISSARIAT À L'ÉNERGIE ATOMIQUE ET AUX ÉNERGIES ALTERNATIVES, Paris (FR); STMICROELECTRONICS (GRENOBLE 2) SAS, Grenoble (FR); STMicroelectronics (Crolles 2) SAS, Crolles (FR)

(72) Inventors: Raphael MULIN, Grenoble (FR); Olivier JEANNIN, Grenoble (FR); Francois DENEUVILLE, Grenoble (FR)

(73) Assignees: COMMISSARIAT À L'ÉNERGIE ATOMIQUE ET AUX ÉNERGIES ALTERNATIVES, Paris (FR); STMICROELECTRONICS (GRENOBLE 2) SAS, Grenoble (FR); STMicroelectronics (Crolles 2) SAS, Crolles (FR)

(21) Appl. No.: 18/942,211

(22) Filed: Nov. 8, 2024

(30) Foreign Application Priority Data
Nov. 22, 2023 (FR) 2312889

(51) Int. Cl. G02B 5/26; G01J 1/44; G02B 5/20; G02B 13/14

(52) U.S. Cl. CPC G02B 5/26; G01J 1/44; G02B 5/208; G02B 13/14; G01J 2001/446

(57) ABSTRACT

The disclosure relates to an optoelectronic device comprising in a stack: one reflection polarizing filter, one phase-shifting element configured to add a π/4 phase shift in polarization, one active region, one reflector, so that the light radiation rays reflected by the reflector and passing through the phase-shifting element exhibit a new polarization phase-shifted by π/2 with respect to their initial polarization, the rays then being reflected anew by the polarizing filter in the direction of the active region.

### BACKGROUND

### Technical Field

The present disclosure relates, in general, to an optical device, and more particularly, to an optical device for an infrared sensor pixel.

### Description of the Related Art

Some spatially resolved infrared sensors feature a pixel architecture. These pixels, typically silicon-based photodiodes, can be formed by processes derived from complementary metal-oxide-semiconductor (CMOS) transistor technologies.

Each pixel can be configured to detect a particular polarization component of infrared radiation. A polarizing filter is then added to each pixel upstream of the active region of the pixel.

An infrared imager that is sensitive to polarization therefore typically comprises a matrix of pixels each comprising, in a stack:
optionally a lens-type optical element;
a polarizing filter;
an active photodiode-type region absorbing the light transmitted by the polarizing filter; and
an underlying level of contacts or interconnections, possibly acting as a reflector for light not absorbed by the active region.

Although functional, such an imager still performs poorly in the infrared due to the low quantum efficiency of the pixels. Infrared light absorption in the active region remains limited. The low quantum efficiency of the pixels limits the ability to miniaturize them. Imager resolution is limited. Light not absorbed by the active region can, moreover, potentially propagate into another pixel, thus creating a source of optical crosstalk that is also detrimental to the resolution of the imager.

To improve the quantum efficiency of pixels, it is possible to form a diffractive structure upstream of the active region, in order to increase the path length of the light propagating in the active region. The document “2021-Photonics West-Pixels with add-on structures to enhance quantum efficiency in the near infrared” by Felix Bardonnet et al. discloses such a diffractive structure for a pixel sensitive in the near infrared. The gain achieved by this solution nevertheless depends on the thickness of the photodiode and the width of the pixels. A compromise between resolution and efficiency remains necessary.

There is therefore a use for improving the quantum efficiency of a pixel, particularly in the infrared, independently of the pixel size.

One task of the present disclosure is to fulfill this use and at least partially alleviate the above-mentioned drawbacks.

One objective of the present disclosure is to provide an optoelectronic device of the photosensitive pixel type that exhibits improved quantum efficiency.

Further objects, features and advantages of the present disclosure will become apparent upon examination of the following description and accompanying drawings. It is understood that further advantages may be incorporated.

### BRIEF SUMMARY

To achieve this objective, according to one embodiment, an optoelectronic device is provided which is configured to capture light radiation of wavelength λ, comprising in a stack along a first direction z:
one reflective polarizing filter, configured to solely transmit light radiation rays exhibiting a first polarization;
one phase-shifting element configured to add a phase shift of π/4 in polarization to the light radiation rays passing through said phase-shifting element;
one active region configured to absorb at least partially the light radiation rays; and
one reflector configured to reflect at least partially the light radiation rays.

In this way, the light radiation rays reflected by the reflector and passing through the phase-shifting element have a new polarization that is out of phase by π/2 compared to the first polarization. The rays exhibiting the new polarization are then once again reflected back to the active region by the polarizing filter. The polarizing filter solely transmits rays exhibiting the first polarization. Rays exhibiting a polarization other than the first polarization are reflected by the polarizing filter.

The path of the light rays in the active region is advantageously increased. Quantum efficiency is improved. The light rays can carry out up to two round trips between the polarizing filter and the reflector. A cavity, which depends on the polarization of the light rays, is thus advantageously formed. This cavity is also known as a “polarizing optical cavity.”

Structurally, the optical cavity is located between the polarizing filter and the reflector, and comprises the phase-shifting element and the active region. This cavity makes it possible to introduce a phase shift of π/4 in polarization at each light radiation path within said cavity.

Functionally, light radiation propagating from the polarizing filter towards the active region can thus undergo a first phase shift of π/4, a first reflection by the reflector, a second phase shift of π/4, a reflection by the polarizing filter, a third phase shift of π/4, a second reflection by the reflector, a fourth phase shift of π/4, a transmission by the polarizing filter. The combination of the polarizing filter, the phase-shifting element, and the reflector advantageously makes it possible to lengthen the optical path in the active region, which is to say, in the photosensitive part of the device according to the disclosure.

According to one aspect, the disclosure also relates to a system comprising a plurality of such devices organized in a matrix, forming an infrared imager.

### BRIEF DESCRIPTION OF THE SEVERAL VIEWS OF THE DRAWINGS

The aims, objects, as well as features and advantages of the disclosure will become clearer from the detailed description of the embodiments thereof which are illustrated by the following accompanying drawings, wherein:

FIG. 1 schematically illustrates, in a cross-section, an optoelectronic device according to one embodiment of the present disclosure.

FIG. 2 schematically illustrates, in cross-section, the operating principle of an optoelectronic device according to one embodiment of the present disclosure.

FIG. 3A and FIG. 3B schematically illustrate, in top view, different embodiments of a polarizing filter of an optoelectronic device according to the present disclosure.

FIG. 4A, FIG. 4B, and FIG. 4C schematically illustrate, in top view, different embodiments of a phase-shifting element of an optoelectronic device according to the present disclosure.

FIG. 5 shows simulated absorption and reflection curves of an optoelectronic device according to the present disclosure, as a function of the thickness of the phase-shifting element.

FIG. 6 schematically illustrates, in cross-section, a system comprising two adjacent optoelectronic devices, according to one embodiment of the present disclosure.

FIG. 7A schematically illustrates, in top view, a polarization sorting element of a system, according to one embodiment of the present disclosure.

FIG. 7B schematically illustrates, in top view, a plurality of adjacent polarizing filters of a system according to one embodiment of the present disclosure.

FIG. 7C schematically illustrates, in top view, a plurality of adjacent phase-shifting elements of a system according to one embodiment of the present disclosure.

FIG. 8A schematically illustrates, in top view, a polarization sorting element of a system, according to another embodiment of the present disclosure.

FIG. 8B schematically illustrates, in top view, a plurality of adjacent polarizing filters of a system according to another embodiment of the present disclosure.

FIG. 8C schematically illustrates, in top view, a plurality of adjacent phase-shifting elements of a system according to another embodiment of the present disclosure.

FIG. 9A and FIG. 9B schematically illustrate, in a top view, different reflector embodiments of an optoelectronic device according to the present disclosure.

The drawings are given by way of example and are not limitative of the disclosure. They are schematic representations intended to facilitate understanding of the disclosure and are not necessarily to the scale of practical applications. In particular, in the schematic diagrams, the thicknesses of the various layers and portions, and the dimensions of the patterns, are not necessarily representative of reality.

### DETAILED DESCRIPTION

Before embarking on a detailed review of embodiments of the disclosure, optional features are set forth below which may optionally be used in combination or alternatively.

According to one example, the active region is a silicon-based photodiode. Such a photodiode can advantageously be produced using standard CMOS technology processes.

According to one example, the polarizing filter comprises a lattice of lines parallel to one another and perpendicular to the first polarization. The lines are orthogonal to the direction of the electric field. The lines can be aluminum- or silicon-based. They are typically embedded in a SiO2-based matrix.

According to one example, the reflector comprises a part of a contact or interconnection level. This enables the reflector to be used for both optical reflection and electrical conduction. It comprises, for example, metal tracks forming an electrical contact with the active region of the device. These metal tracks can be arranged in the form of a grid in order to adjust the reflective properties of the reflector.

According to one example, the phase-shifting element comprises a lattice of lines parallel to one another and forming an angle of 45° with the first polarization. An efficient phase-shifting element can thereby be obtained, one that does not use a large thickness to achieve effective phase-shifting. The lines can be silicon-based. They are typically embedded in a SiO2-based matrix.

According to one example, the phase-shifting element takes the form of a metasurface comprising a lattice of ellipses the major axes of which are directed in a direction forming an angle of 45° with the first polarization. A phase-shifting element with improved transmission can thereby be obtained. The ellipses can be silicon-based. They are typically embedded in a SiO2-based matrix.

According to one example, the phase-shifting element is in contact with the active region. This reduces the height of the stack. This increases the compactness of the device.

According to one example, the device, moreover, comprises at least one reflective wall that laterally borders the active region. This makes it possible to improve the collection of rays propagating in a direction not parallel to the first direction z. This reduces optical crosstalk between two adjacent devices.

According to one example, the wavelength λ of the light radiation belongs to the infrared range. The wavelength λ is, for example, between 920 nm and 960 nm.

According to one example, the phase-shifting element has a thickness along the first direction z in the order of 0.8 μm. This makes it possible to optimize the function of the phase-shifting element for rays with wavelengths λ in the infrared range having different propagation directions.

According to one example, the system comprises at least one first device and one second device adjacent along a direction y normal to the first direction z, the first device comprising a polarizing filter configured to solely transmit light radiation rays exhibiting a first polarization and the second device comprising a polarizing filter configured to solely transmit light radiation rays exhibiting a second polarization. The system can, moreover, comprise a polarization sorting element on the first and second devices, configured to direct rays exhibiting the first polarization towards the first device and to direct rays exhibiting the second polarization towards the second device. This makes it possible to produce sensors that are sensitive to polarization, typically to form an imager for obtaining a plurality of polarized images of the same light radiation.

Unless it is incompatible, it is understood that all of the above optional features may be combined to form an embodiment which is not necessarily illustrated or described. Such an embodiment is obviously not excluded from the disclosure. The features and advantages of the device according to the disclosure can be applied, mutatis mutandis, to the features and advantages of the system according to the disclosure, and vice versa.

It is specified that, in the context of the present disclosure, the terms “on,” “sits atop,” “covers,” “underlying,” “opposite,” and their equivalents, do not necessarily mean “in contact with.” In this way, for example, the deposition or formation of a first layer on a second layer does not necessarily mean that the two layers are directly in contact with one another, but means that the first layer at least partially covers the second layer, either by being directly in contact with it, or by being separated from it by at least one other layer or at least one other element.

A layer can also be composed of a plurality of sub-layers of the same or different materials.

When speaking of a substrate, a stack, a layer, an element “-based” on a material A, this is understood to be a substrate, a stack, a layer, an element comprising solely this material A or this material A and optionally other materials, for example, alloying elements and/or doping elements.

A preferably orthonormal reference frame, comprising the x, y, z axes, is shown in the appended figures. When a single reference frame is shown on a single sheet of the figures, this reference frame applies to all the figures on that sheet.

In the present patent application, the thickness of one layer is taken along a direction normal to the main extension plane of the layer. Thus, a layer typically has a thickness along z. The relative terms “on,” “sits atop,” “under,” “underlying,” “interleaved” refer to positions taken along direction z.

The terms “vertical,” “vertically” refer to a direction along z. The terms “horizontal,” “horizontally,” “lateral,” “laterally” refer to a direction in the xy plane. Unless explicitly stated, thickness, height and depth are measured along z.

An element located “in plumb” or “in line” with another element means that these two elements are both located on the same line perpendicular to a plane in which a bottom or top surface of a substrate mainly extends, which is to say, on the same line oriented vertically on the figures.

In the context of the present disclosure, the phase-shifting element is configured to phase-shift the polarization of the light by π/4. This function corresponds to that of a quarter-wave plate. The phase-shifting element may therefore also be referred hereinafter to as a “quarter-wave plate.”

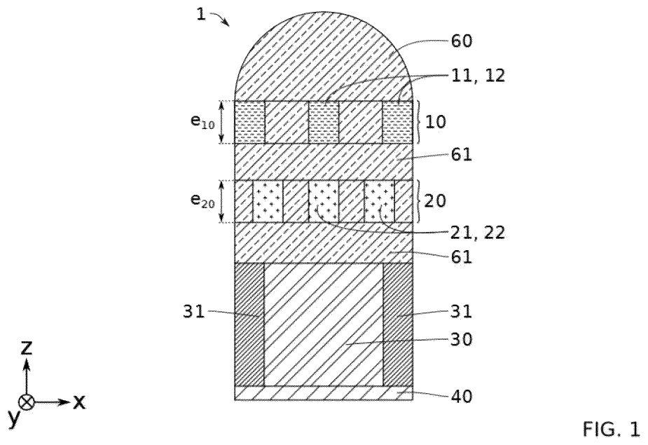

FIG. 1 illustrates one embodiment of the optoelectronic device 1. This optoelectronic device 1 typically comprises in a stack along z:
one optional optical element 60, typically a lens or micro-lens, intended to increase the numerical aperture of the device;
one reflective polarizing filter 10, configured to transmit a polarized light, typically to transmit a state of polarization, and reflect the state of polarization orthogonal to the transmitted state;
one or a plurality of interposing elements 61, for example, in the form of SiO2-based layers, configured to optimize the propagation of the polarized light;
one phase-shifting element 20 configured to add a phase shift of π/4 in polarization to the light passing through said phase-shifting element 20;
one active region 30 configured to absorb the polarized light, at least in part; and
one reflector 40 configured to reflect the polarized light, at least in part.

The reflective polarizing filter 10 may take the form of a layer comprising a lattice of lines 11, 12 embedded in a SiO2-based matrix. These lines 11, 12 may be silicon- or aluminum-based. The polarizing filter 10 typically has a thickness e₁₀. Such a polarizing filter 10 can be easily integrated and implemented using CMOS technology. Different embodiments of the reflective polarizing filter 10 are described and illustrated hereinafter.

The phase-shifting element 20 may be in the form of a layer comprising a lattice of lines or patterns 21, 22 embedded in a SiO2-based matrix. These lines or patterns 21, 22 may be silicon-based. The phase-shifting element 20 typically has a thickness e₂₀. Such a phase-shifting element 20 can be easily integrated and implemented using CMOS technology. The phase-shifting element 20 can be formed directly on the active region 30, for example, by etching. There is not necessarily an interposing element 61 between the phase-shifting element 20 and the active region 30. Different embodiments of the phase-shifting element 20 are described and illustrated hereinafter.

The active region 30 is preferably silicon-based. It is preferably bordered by reflective walls 31, for example, in the form of deep aluminum-based trenches.

The reflector 40 is typically formed by a lattice of metal lines in electrical contact with the active region 30. It therefore ensures an optical reflection function and an electrical conduction function. It can typically correspond to part of a metal level in CMOS technology.

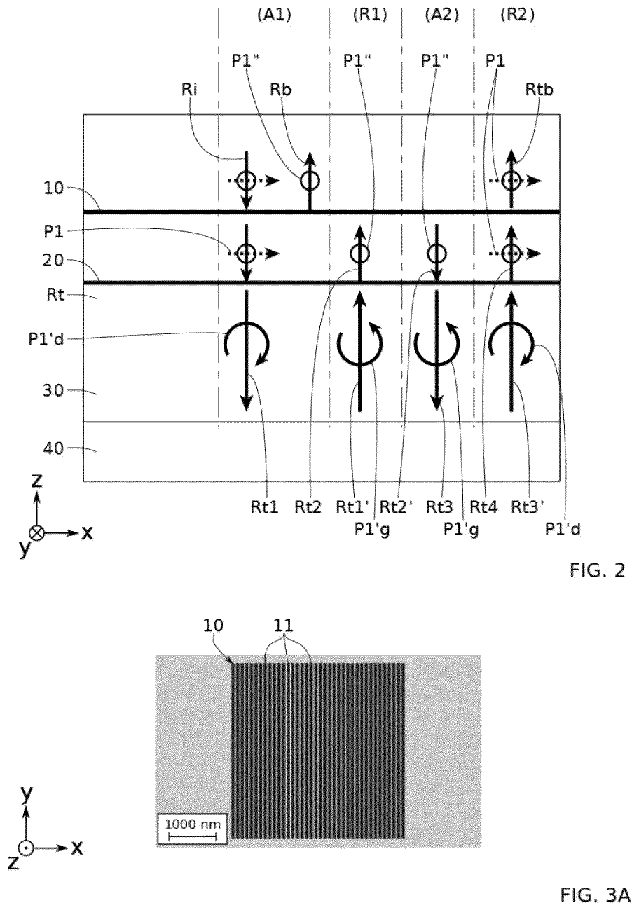

FIG. 2 illustrates an operating principle of the optoelectronic device 1. The optoelectronic device 1 operates in part as an optical cavity between the polarizing filter 10 and the reflector 40, for certain polarized rays of the incident light. On FIG. 2, four successive phases (A1), (R1), (A2), (R2), corresponding to the back and forth movements of light within the optical cavity of the device, are detailed. During the first phase (A1), typically unpolarized incident rays Ri propagate from the top to the bottom, in the direction of the polarizing filter 10. These incident rays Ri are filtered by the polarizing filter 10. Exclusively the rays Rt exhibiting polarization P1 are transmitted by the polarizing filter 10. The polarization P1 corresponds, for example, to Transverse Electrical (TE) polarization. The rays Rt exhibiting polarization P1 then propagate in the direction of the phase-shifting element 20. After passing through the phase-shifting element 20, the rays Rt become rays Rt1 exhibiting a polarization P1′d that is phase-shifted by π/4 with respect to the P1 polarization. In the case of a TE-type polarization P1, polarization P1′d typically corresponds to right-hand circular polarization. A part of the rays Rt1 exhibiting a polarization P1′d are absorbed by the active region 30. The rays Rt1 exhibiting a polarization P1′d not absorbed by the active region 30 are then reflected by the reflector 40. During the second phase (R1), the rays propagate from the bottom to the top. The rays Rt1 exhibiting a polarization P1′d reflected by reflector 40 become rays Rt1′ exhibiting a polarization P1′g. In the case of TE-type polarization P1, the polarization P1′g typically corresponds to left-hand circular polarization. A part of the rays Rt1′ exhibiting a polarization P1′g are absorbed by the active region 30. The rays Rt1′ exhibiting polarization P1′g that are not absorbed by the active region 30 propagate towards the phase-shifting element 20. After passing through the phase-shifting element 20, the rays Rt1′ become rays Rt2 exhibiting a polarization P1″ that is π/4 out of phase exhibiting the polarization P1′g. In the case of TE-type polarization P1, the P1″ polarization typically corresponds to Transverse Magnetic (TM) polarization. The rays Rt2 exhibiting a polarization P1″ are then advantageously reflected by the polarizing filter 10. During the third phase (A2), the rays propagate from the top to the bottom. The P1″ polarized Rt2 rays reflected by the polarizing filter 10 become P1″ polarized Rt2′ rays. The rays Rt2′ exhibiting a polarization P1″ propagate once again towards the phase-shifting element 20. After passing through the phase-shifting element 20, the rays Rt2′ become rays Rt3 exhibiting a polarization P1′g, phase-shifted by π/4 with respect to the polarization P1″. A part of the rays Rt3 exhibiting a polarization P1′g is once again absorbed by the active region 30. The rays Rt3 exhibiting a polarization P1′g that is not absorbed by the active region 30 are then reflected by the reflector 40. During the fourth phase (R2), the rays propagate from the bottom to the top. The rays Rt3 exhibiting a polarization P1′g reflected by reflector 40 become rays Rt3′ exhibiting a polarization P1′d. A part of the rays Rt3′ exhibiting a polarization P1′d is once again absorbed by the active region 30. The rays Rt3′ exhibiting a polarization P1′d that are not absorbed by the active region 30 propagate towards the phase-shifting element 20. After passing through the phase-shifting element 20, the rays Rt3′ become rays Rt4 exhibiting the polarization P1 phase-shifted by π/4 with respect to the polarization P1′d. The rays Rt4 exhibiting a polarization P1 are then transmitted by the polarizing filter 10, and become rays Rtb exhibiting a polarization P1.

The rays thus typically make two round trips in the optical cavity before eventually exiting the device. The path of the light rays is thus advantageously doubled in this device provided with a quarter-wave plate-type phase-shifting element, in comparison with a device without such a phase-shifting element. The absorption of polarized rays in the active region 30 can occur on four occasions, during each of the round-trip phases (A1), (R1), (A2), (R2). The absorption of polarized rays by the device is thereby improved.

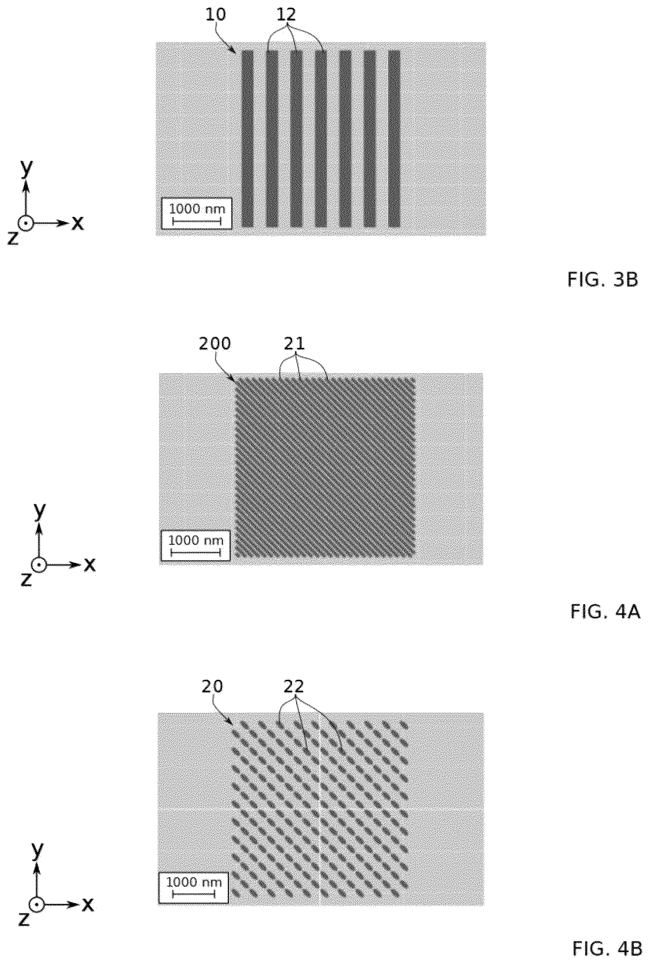

FIG. 3A illustrates one embodiment of the polarizing filter 10. Here, the polarizing filter 10 is formed by a lattice of aluminum-based lines 11 in a silicon oxide matrix. In the case of a metal-grid polarizing filter, the orientation of P1 is perpendicular to that of the grid. Lines 11 are oriented along the y axis. The pitch of the lattice is measured along x, and it is indeed polarization x that is 90% and the polarization y is 1%. Such a polarizing filter transmits light rays exhibiting polarization parallel to the x axis and rejects light rays exhibiting polarization perpendicular to the x axis. The polarizing filter 10 comprising metallic lines 11 advantageously has little sensitivity to the angle of incidence of the light rays. For light rays in the infrared range, a polarizing filter 10 with a thickness c₁₀ in the order of 250 nm is preferred, with a pitch of the lattice p≤250 nm along x, and a filling factor f≤30% (the filling factor f being the ratio of the width of a line along y on the pitch of the lattice). This gives a transmission of around 90% for rays polarized along x, while maintaining a transmission of less than 1% for rays polarized along y.

FIG. 3B illustrates a further embodiment of the polarizing filter 10. Here, the polarizing filter 10 is formed by a lattice of silicon-based lines 12 in a silicon oxide matrix. The lines 11 are oriented along the y axis. The pitch of the lattice p, along x, can be larger here, typically in the order of 500 nm. This relaxes the constraint on spatial resolution used to manufacture such a lattice. The cost of the polarizing filter 10 can thus be reduced. For light rays in the infrared range, typically 920 nm≤λ≤960 nm, a polarizing filter 10 with a thickness e₁₀ in the order of 550 nm is preferred, with a pitch of the lattice p in the order of 505 nm along x, and a fill factor f in the order of 42%. Alternatively, a polarizing filter 10 with a thickness c₁₀ in the order of 120 nm, a pitch of the lattice p in the order of 525 nm along x, and a filling factor f in the order of 42% may be selected.

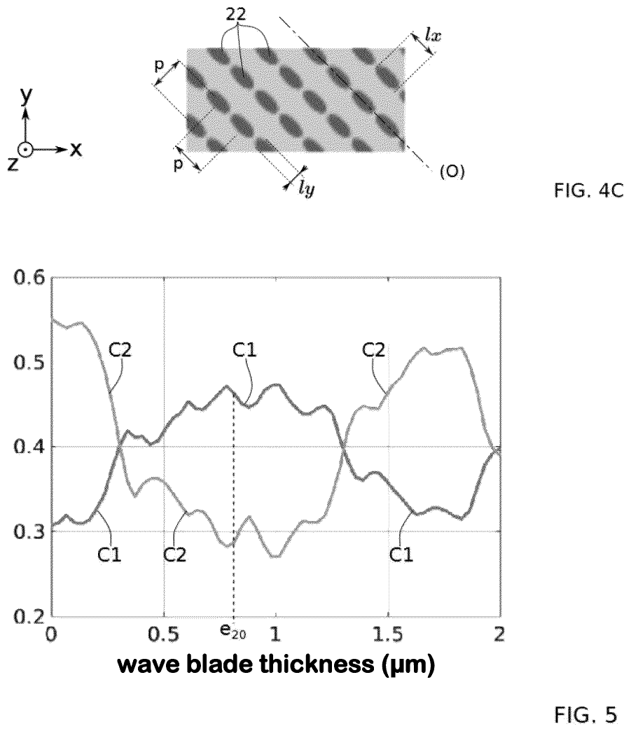

FIG. 4A illustrates an embodiment of the phase-shifting element 20. Here, the phase-shifting element 20 is formed by a lattice of silicon-based lines 21 in a silicon oxide matrix. The lines 21 are typically oriented at 45° with respect to the x axis. For light rays in the infrared range, a phase-shifting element 20 with a thickness e₂₀ in the order of 300 nm is preferred, with a pitch of the lattice p≤300 nm, typically 50 nm≤p≤250 nm, and a fill factor f in the order of 50%. This makes it possible to obtain an effective quarter-wave plate for TE and TM modes of light propagation, with a transmission greater than 90%, close to 100%.

FIG. 4B and FIG. 4C illustrate another embodiment of the phase-shifting element 20. Here, the phase-shifting element 20 is formed by a lattice of silicon-based ellipses 22 in a silicon oxide matrix. The ellipses 22 typically have a major axis (O) oriented at 45° with respect to the x-axis. For light rays in the infrared range, a phase-shifting element 20 with a thickness e₂₀ of between 700 nm and 800 nm, a pitch of the lattice p≤300 nm and a fill factor f in the order of 25% is preferred. The ellipses 22 typically have a dimension lx of 225 nm along the major axis (O), and a dimension ly of 75 nm along the minor axis.

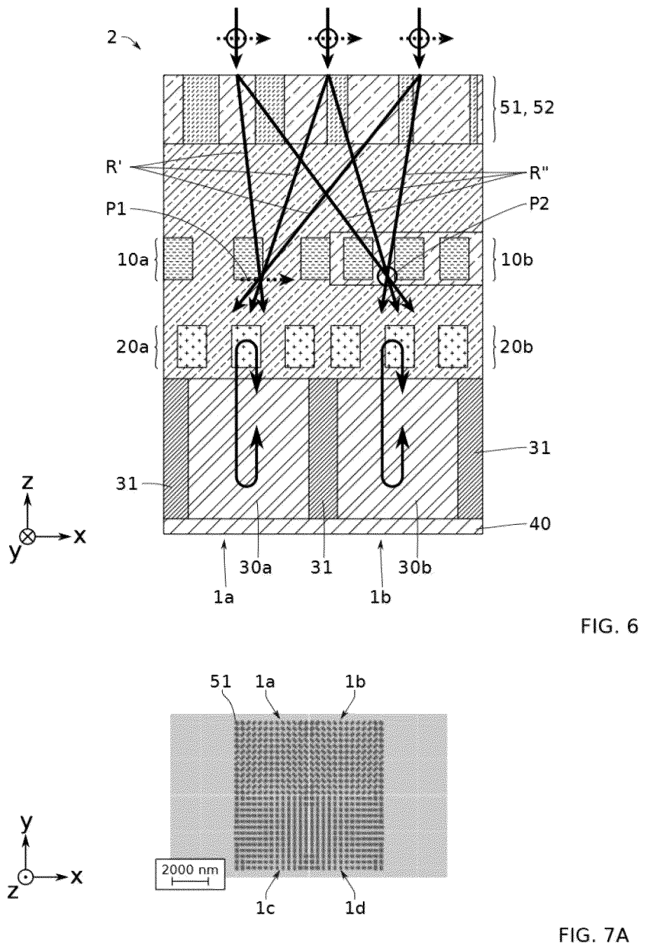

FIG. 5 shows a model of the absorption (curve C1) in the active region 30 as well as the reflection (curve C2) of light above the device, as a function of the thickness e₂₀ of the phase-shifting element 20. Here, the phase-shifting element 20 corresponds to the silicon-based lattice of ellipse 22 oriented at 45°. Curves C1, C2 are averaged over 5 wavelengths comprised between 920 nm and 960 nm. Absorption is a criterion to be maximized and reflection is a criterion to be minimized. The optimum e₂₀ thickness, corresponding to a quarter-wave plate, is in the order of 0.8 μm.

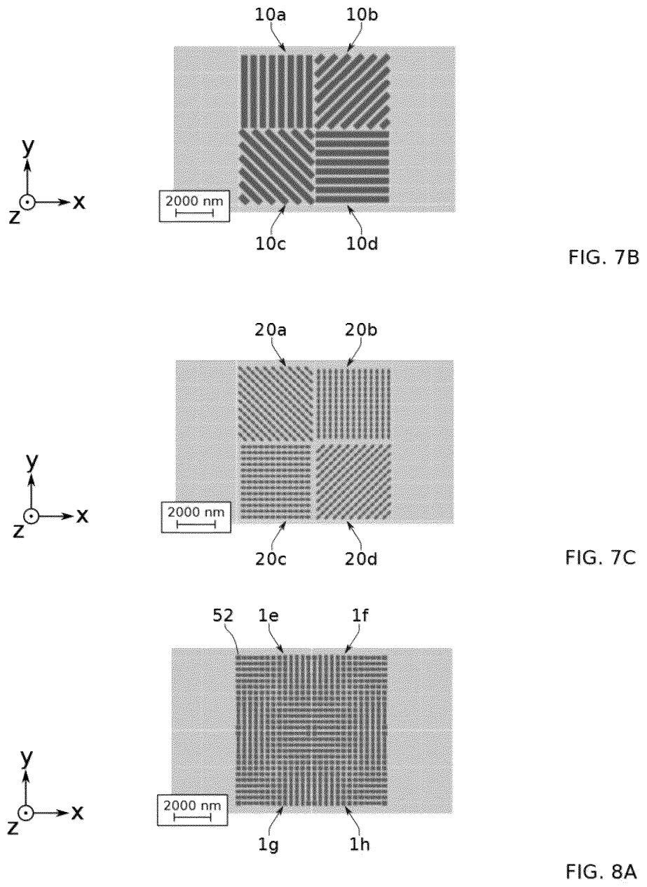

FIG. 6 shows a cross-section of a system 2 comprising two adjacent devices 1a, 1b along y. The first device 1a comprises a polarizing filter 10a configured to transmit solely rays R′ of the light radiation exhibiting a first polarization P1. The second device 1b comprises a polarizing filter 10b configured to transmit solely rays R″ of the light radiation exhibiting a second polarization P2. The system 2 further comprises, on the first and second devices 1a, 1b, a polarization sorting element 51, 52 configured to direct rays R′ towards the first device 1a and to direct rays R″ towards the second device 1b. In the first device 1a, the polarizing filter 10a transmits the rays R′ to the phase-shifting element 20a and, as previously described with regards to the device, the rays R′ make several round trips between the phase-shifting element 20a and the reflector 40, passing through the active region 30a. The rays R′ are thus more effectively absorbed by the first device 1a. In the same manner, in the second device 1b, the polarizing filter 10b transmits the rays R″ to the phase-shifting element 20b, and the rays R″ make several round trips between the phase-shifting element 20b and the reflector 40, passing through the active region 30b. The rays R″ are thus more effectively absorbed by the second device 1b. The active regions 30a, 30b are preferably separated by reflective walls 31, that are typically aluminum-based, to avoid or limit optical crosstalk between devices, and to maximize absorption in active regions 30a, 30b. The system 2 thus comprises devices, typically pixels, sensitive to different polarizations of the incident light. Such a system 2 can be used, for example, to create an infrared imager that is sensitive to the polarization, capable of producing different polarized images from the same light source.

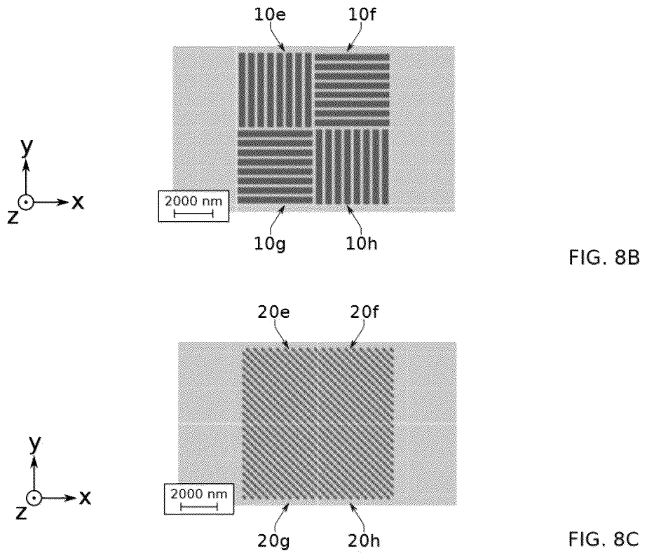

FIG. 7A shows a top view of an embodiment of a polarization sorting element 51 covering an elementary matrix of four pixels 1a, 1b, 1c, 1d. Each pixel 1a, 1b, 1c, 1d is sensitive to one polarization, for example, 0°, 45°, 90°, 135° respectively. The polarization sorting element 51 is formed here by a lattice of silicon-based patterns in a silicon oxide matrix. The patterns are defined and oriented according to the polarization to be transmitted and according to the position of the pixel configured to receive the rays polarized according to this polarization.

FIG. 7B shows a top view of the polarizing filters 10a, 10b, 10c, 10d of the corresponding pixels 1a, 1b, 1c, 1d. Each polarizing filter 10a, 10b, 10c, 10d is configured to transmit rays exhibiting a given polarization, for example, 0°, 45°, 90°, 135° respectively. Here, the polarizing filters 10a, 10b, 10c, 10d are formed by lattices of silicon-based lines in a silicon oxide matrix. The orientation of these lines is defined according to the polarization of the rays to be transmitted to the underlying active region.

FIG. 7C shows a top view of the phase-shifting elements 20a, 20b, 20c, 20d of the corresponding pixels 1a, 1b, 1c, 1d. Each phase-shifting element 20a, 20b, 20c, 20d is configured to shift the polarization of the transmitted rays by π/4. Here, the phase-shifting elements 20a, 20b, 20c, 20d are formed by lattices of silicon-based ellipses in a silicon oxide matrix. The orientation of the major axis of these ellipses is defined as a function of the orientation of the lines of the polarizing filters 10a, 10b, 10c, 10d, that respect an offset of 45° with respect to the orientation of the lines of the corresponding polarizing filters 10a, 10b, 10c, 10d. The major axes of the ellipses of the phase-shifting elements 20a, 20b, 20c, 20d are, for example, oriented at 45°, 90°, 135°, 180° respectively.

A system 2 comprises one or more elementary matrices of pixels 1a, 1b, 1c, 1d sensitive to polarization forms, for example, an imager that is sensitive to polarization.

It is also possible to implement the disclosure in a system 2 that is not sensitive to polarization.

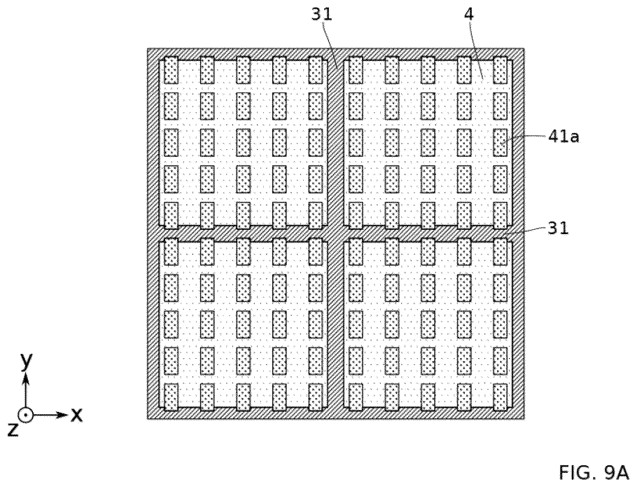

FIG. 8A shows a top view of an embodiment of a polarization sorting element 52 covering an elementary matrix of four pixels 1e, 1f, 1g, 1h. The pixels 1e, 1h are sensitive to the same first polarization, typically 0°. The pixels 1f, 1g are sensitive to the same second polarization, that is complementary to the first polarization, typically 90°. Here, the polarization sorting element 52 is formed by a lattice of silicon-based patterns in a silicon oxide matrix. The patterns are defined and oriented according to the polarization to be transmitted and according to the position of pixels configured to receive rays polarized according to this polarization. The polarization sorting element 52 typically has a central symmetry.

FIG. 8B shows a top view of the polarizing filters 10e, 10f, 10g, 10h of the corresponding pixels 1e, 1f, 1g, 1h. Each polarizing filter 10e, 10f, 10g, 10h is configured to transmit rays exhibiting a given polarization, for example, 0°, 90°, 0°, 90° respectively. Here the polarizing filters 10c, 10f, 10g, 10h are formed by lattices of silicon-based lines in a silicon oxide matrix. The orientation of these lines is defined according to the polarization of the rays to be transmitted to the underlying active region.

FIG. 8C shows a top view of the phase-shifting elements 20e, 20f, 20g, 20h of the corresponding pixels 1e, 1f, 1g, 1h. Each phase-shifting element 20e, 20f, 20g, 20h is configured to shift the polarization of the transmitted rays by π/4. Here, the phase-shifting elements 20c, 20f, 20g, 20h are formed by lattices of silicon-based ellipses in a silicon oxide matrix. The orientation of the major axis of these ellipses is defined as a function of the orientation of the lines of the polarizing filters 10c, 10f, 10g, 10h, while respecting an offset of 45° with respect to the orientation of the lines of the corresponding polarizing filters 10e, 10f, 10g, 10h. The major axes of the ellipses of the phase-shifting elements 20c, 20f, 20g, 20h are, for example, all oriented at 45° in this embodiment.

By coupling pixels 1e, 1f and pixels 1g, 1h in pairs, it is possible to obtain an imager that is not sensitive to polarization with improved light detection efficiency (via the polarizing optical cavity integrated in each pixel). The disclosure can therefore be advantageously implemented in systems that are not sensitive to polarization.

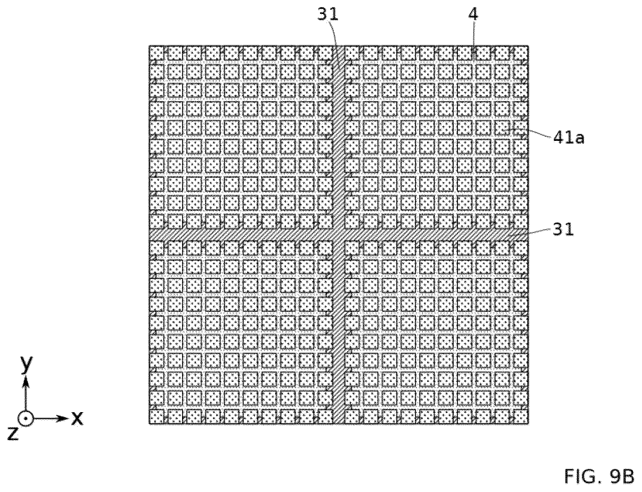

FIG. 9A and FIG. 9B illustrate in top view two respective embodiments of a reflector in an elementary matrix of four pixels separated by walls 31. In these two embodiments, the reflector comprises a lattice of metal pads 41a, for example, copper-based, in silicon 4. Advantageously, these metal pads 41a are used to make electrical contact with the active regions located there-above. Only the size of the metal pads and the metal fill factor (ratio of metal surface to silicon surface) differ between the two embodiments.

Table 1 shows different results (quantum efficiency QE and contrast C) stemming from simulations for systems comprising different device configurations. The first row in Table 1, titled “direct lighting,” corresponds to a configuration comprising an active region with an underlying reflector, with no other element sitting atop the active region. The second row in Table 1, titled “sorter+reflector,” corresponds to a configuration comprising an active region, exhibiting a polarization sorting element sitting atop it, and an underlying reflector. The third row in Table 1, titled “sorter+phase shifter,” corresponds to a configuration comprising an active region, exhibiting a polarization sorting element and a phase-shifting element sitting atop, with no underlying reflector. The fourth row in Table 1, titled “sorter+phase shifter+reflector,” corresponds to a configuration comprising an active region, exhibiting a polarization sorting element and a phase shifting element sitting atop, and comprising an underlying reflector. The fifth row in Table 1, titled “sorter+diffraction+reflector,” corresponds to a configuration comprising an active region, exhibiting a polarization sorting element and a known diffractive structure sitting atop, and comprising an underlying reflector. Two columns “Reflector A” and “Reflector B” correspond respectively to the reflector configurations shown on FIGS. 9A and 9B.

TABLE 1

| | Reflector A | Reflector B |
|---|---|---|
| direct lighting | QE: 22.0 | QE: 26.4 |
| sorter + reflector | QE: 22.4% - C: 10 | QE: 26.0% - C: 8.1 |
| sorter + phase shifter | QE: 32.0% - C: 1.6 | |
| sorter + phase shifter + | QE: 33.0% - C: 8.2 | QE: 56% - C: 14 |
| reflector | | |
| sorter + diffraction + reflector | — | QE: 48.0% - C: 9.2 |

The best performance of the pixels is obtained for maximum quantum efficiency QE and maximum contrast C.

The performances increase when the metal fill factor increases (reflector B has a higher metal fill factor than reflector A).

The absence of a reflector adversely affects contrast (expressed as the ratio of the transmitted polarization component to the rejected polarization component), notwithstanding the presence of the polarization sorting element.

It appears that the best performances are obtained for the configuration comprising the combination of the polarization sorting element, the phase shifting element, and the reflector.

Such a configuration is, moreover, more efficient than a known configuration comprising a diffractive structure. It therefore appears that the configuration proposed by the present disclosure can advantageously be implemented in systems that are both sensitive and not sensitive to polarization.

Other system configurations including an optoelectronic device as described above are possible. These variants are not necessarily illustrated, but can be easily deduced by combining the features of the described embodiments.

The disclosure is not limited to the aforementioned described embodiments.

An optoelectronic device (1) configured to capture light radiation (Ri) of wavelength λ, is summarized as including in a stack along a first direction z: one reflective polarizing filter (10), configured to solely transmit light radiation rays (Rt, Rtb) exhibiting a first polarization (P1), one phase-shifting element (20) configured to add a phase shift of π/4 in polarization to the light radiation rays (Rt1, Rt2, Rt3, Rt4) passing through said phase-shifting element (20), one active region (30) configured to absorb at least partially the light radiation rays (Rt1, Rt1′, Rt3, Rt3′), one reflector (40) configured to at least partially reflect the light radiation rays (Rt1, Rt1′, Rt3, Rt3′), so that the light radiation rays (Rt1′, Rt2) reflected by the reflector (40) and passing through the phase-shifting element (20) exhibit a new polarization (P1″) that is phase-shifted by π/2 with respect to the first polarization (P1), the said rays (Rt2, Rt2′) exhibiting the new polarization (P1″) are then reflected back by the polarizing filter (10) towards the active region (30).

The active region (30) is a silicon-based photodiode.

The polarizing filter (10) includes a lattice of lines (11, 12) parallel to one another and perpendicular to the first polarization (P1).

The reflector (40) includes a part of a contact or interconnection level.

The phase-shifting element (20) includes a lattice of lines (21) parallel to one another and forming an angle of 45° with the first polarization (P1).

The phase-shifting element (20) is in the form of a metasurface including a lattice of ellipses (22) the major axes (O) of which are directed in a direction forming an angle of 45° with the first polarization (P1).

The phase-shifting element (20) is in contact with the active region (30).

The device (1) further includes at least one reflective wall (31) that laterally borders the active region (30).

The wavelength λ of the light radiation belongs to the infrared range.

The phase-shifting element (20) has a thickness e₂₀ along the first direction z in the order of 0.8 μm.

A system (2) is summarized as including a plurality of devices (la, 1b) organized in a matrix, forming an infrared imager.

The system (2) includes at least one first device (la) and one second device (1b) adjacent along a direction (y) normal to the first direction (z), the first device (la) including a polarizing filter (10a, 10e) configured to transmit solely light radiation rays (R′) exhibiting a first polarization (P1) and the second device (1b) including a polarizing filter (10b, 10f) configured to solely transmit light radiation rays (R″) exhibiting a second polarization (P2), the system (2), moreover, including a polarization sorting element (51, 52) on the first and second devices (1a, 1b), configured to direct rays (R′) exhibiting the first polarization (P1) towards the first device (la) and to direct rays (R″) exhibiting the second polarization (P2) towards the second device (1b).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An optoelectronic device, comprising:
a reflective polarizing filter, configured to solely transmit light radiation rays exhibiting a first polarization;
a phase-shifting element configured to add a phase shift of π/4 in polarization to the light radiation rays passing through the phase-shifting element;
an active region configured to absorb at least partially the light radiation rays, the phase-shifting element being between the polarizing filter and the active region in a stack along a first direction; and
a reflector configured to at least partially reflect the light radiation rays, so that the light radiation rays reflected by the reflector and passing through the phase-shifting element exhibit a second polarization that is phase-shifted by π/2 with respect to the first polarization, the rays exhibiting the second polarization being reflected back by the polarizing filter towards the active region, the reflector being coupled to the active region opposite the phase-shifting element along the first direction.

2. The device according to claim 1 in which the active region is a silicon-based photodiode.

3. The device according to claim 1 in which the polarizing filter includes a lattice of lines parallel to one another and transverse to the first polarization.

4. The device according to claim 1 in which the reflector includes a part of a contact or interconnection level.

5. The device according to claim 1 in which the phase-shifting element includes a lattice of lines substantially parallel to one another and forming an angle of 45° with the first polarization.

6. The device according to claim 1 in which the phase-shifting element is a metasurface including a lattice of ellipses the major axes of which are directed in a second direction forming an angle of 45° with the first polarization.

7. The device according to claim 1 in which the phase-shifting element is in contact with the active region.

8. The device according to claim 1 further comprising at least one reflective wall that borders the active region along a second direction transverse to the first direction.

9. The device according to claim 1 in which a wavelength of the light radiation belongs to the infrared range.

10. The device according to claim 1 in which the phase-shifting element has a thickness along the first direction in the order of 0.8 μm.

11. The device according to claim 1, further comprising a first interposing element between the polarizing filter and the phase-shifting element along the first direction.

12. The device according to claim 11, further comprising a second interposing element between the phase-shifting element and the active region along the first direction.

13. The device according to claim 12, wherein the first and second interposing elements include silicon dioxide.

14. A system comprising:
a first device including:
a first polarizing filter configured to transmit solely light radiation rays exhibiting a first polarization;
an active region configured to absorb the light radiation rays;
a phase-shifting element between the first polarizing filter and the active region along a first direction; and
a reflector opposite the active region from the phase-shifting element along the first direction;
a second device coupled to the first device along a second direction transverse to the first direction, the second device including a polarizing filter configured to solely transmit light radiation rays exhibiting a second polarization; and
a polarization sorting element on the first and second devices configured to direct light radiation rays exhibiting the first polarization towards the first device and to direct light radiation rays exhibiting the second polarization towards the second device.

15. The system according to claim 14, wherein the reflector is configured to at least partially reflect the light radiation rays, the light radiation rays reflected by the reflector and passing through the phase-shifting element exhibiting a third polarization phase-shifted by π/2 with respect to the first polarization, the light radiation rays exhibiting the third polarization being reflected by the first polarizing filter towards the active region.

16. A device, comprising:
an active region with a first side opposite a second side along a first direction;
a reflector on the second side of the active region;
a phase-shifting element on the first side of the active region; and
a reflective polarizing filter on a first side of the phase-shifting element opposite the active region.

17. The device according to claim 16, further comprising a lens on a first face of the reflective polarizing filter opposite the phase-shifting element along the first direction.

18. The device according to claim 16, further comprising a first interposing layer between the polarizing filter and the phase-shifting element and a second interposing layer between the phase-shifting element and the active region.

19. The device according to claim 16, wherein the polarizing filter includes a lattice of lines transverse to a first polarization of light radiation rays.

20. The device according to claim 19, wherein the phase-shifting element is configured to add a phase shift of π/4 in polarization to the light radiation rays and the active region is configured to partially absorb the light radiation rays.
